(19) United States
(12) Patent Application Publication
(10) Pub. No.: US 2025/0335669 A1
(43) Pub. Date: Oct. 30, 2025

(54) Waveform-Analyzing Method and Waveform-Analyzing Device

(71) Applicant: SHIMADZU CORPORATION, Kyoto-shi (JP)

(72) Inventor: Shinji KANAZAWA, Kyoto-shi (JP)

(21) Appl. No.: 19/189,409

(22) Filed: Apr. 25, 2025

(30) Foreign Application Priority Data
Apr. 25, 2024 (JP) 2024-071491

(51) Int. Cl. G06F 30/27

(52) U.S. Cl. CPC G06F 30/27

(57) ABSTRACT

A trained-model storage section (44) holds two trained models. The first trained model, constructed by machine learning in which a first window is applied to first reference waveform data, outputs a first index representing a peak portion or non-peak portion for first partial data. The second trained model, constructed by machine learning in which a second window having a different width from the first window is applied to second reference waveform data, outputs a second index representing a peak portion or non-peak portion for second partial data. A first-index output processor (55) inputs first analysis-target partial data into the first trained model to obtain an output of the first index. A second-index output processor (56) inputs second analysis-target partial data into the second trained model to obtain an output of the second index. A peak portion estimator estimates a peak portion from the outputs of the first and second indices.

### TECHNICAL FIELD

The present invention relates to a method and device for analyzing a waveform acquired by a measurement of a sample by means of an analyzer.

### BACKGROUND ART

Liquid chromatographs and gas chromatographs have been used for identifying a component contained in a sample and/or determining its quantity. In a chromatograph, the components contained in a sample are separated from each other by a column, and the components which sequentially exit from the column are detected. A chromatogram with the horizontal axis representing time and the vertical axis representing detection intensity is subsequently created. A peak is detected in the chromatogram and the concentration and/or content of a compound corresponding to that peak is determined from the area or height of the peak. A technique in which a spectrum waveform is acquired from a liquid chromatograph or gas chromatograph has also been commonly used. The spectrum waveform, which has the horizontal axis representing the wavelength or mass-to-charge ratio and the vertical axis representing the detection intensity, is often used for substance identification.

To date, various methods for detecting a peak in a chromatogram have been in practical use. In recent years, methods which employ machine learning have been proposed and put into practical use as new peak detection methods (for example, see Patent Literature 1 as well as Non Patent Literatures 1 and 2).

Patent Literature 1 describes a waveform-analyzing technique in which a trained model is constructed by machine learning in which a plurality of sets of reference waveform data, with the positions of their respective peak portions previously known, are used as teaching data, and a peak portion included in the data of a waveform to be analyzed is estimated by means of that trained model. In an example described in the document, the trained model is constructed from a learning model which uses the technique of semantic segmentation used in the area of image analysis, by performing machine learning of this model in which data of a plurality of extracted ion chromatograms (EIC) acquired by a selected ion monitoring (SIM) or multiple reaction monitoring (MRM) measurement, with the positions of their respective peak portions previously known, are used as teaching data. In an actual analysis of an extracted ion chromatogram acquired by a SIM or M RM measurement, a specified number of points of measurement data extracted from that chromatogram are fed into the trained model, which outputs an index (label) that shows whether each point of data belongs to a peak portion or non-peak portion. A frame (extraction range) is used when the specified number of points of measurement data to be fed into the trained model are extracted from the one-dimensional data constituting the waveform being analyzed. This frame is called the “window”.

### CITATION LIST

### Patent Literature

Patent Literature 1: WO 2021/064924 A

### Non Patent Literature

Non Patent Literature 1: “Peakintelligence™ for GCMS—LabSolutions Insight™ Muke Hakei Shori Sofutouea (Peakintelligence™ for GCMS—Peak Processing Software for LabSolutions Insight™)”, [online], [accessed on Mar. 14, 2024], Shimadzu Corporation, the Internet

Non Patent Literature 2: “Peakintelligence™ for LCMS—LabSolutions™ LCMS, LabSolutions Insight™ Muke Hakei Shori Opushon Sofutouea (Peakintelligence™ for LCMS—Peak Processing Optional Software for LabSolutions™ LCMS and LabSolutions Insight™)”, [online], [accessed on Mar. 14, 2024], Shimadzu Corporation, the Internet

Non Patent Literature 3: Takero Sakai, Shinji Kanazawa, “Peakintelligence™ for GCMS™ Ni Yoru Nouyaku Deeta Kaiseki Jikan No Tanshuku (Time-Saving Effect of Peakintelligence™ for GCMS™ on Pesticide Data Analysis)”, [online], [accessed on Mar. 14, 2024], Shimadzu Corporation, the Internet

Non Patent Literature 4: “Nexera-i MT Ni Yoru Oushuu Yakkyokukata Ni Junkyo shita Iyakuhin Fujunbutsu Bunseki No Kousokuka (Use of Nexera-i MT for High-Speed Analysis of Impurities in Drug According to European Pharmacopeia)”, [online], [accessed on Mar. 14, 2024], Shimadzu Corporation, the Internet

### SUMMARY OF INVENTION

### Technical Problem

In the case of analyzing a known kind of target component contained in a sample (“target analysis”), a mass analyzer is used as the detector, for example, and an SIM or MRM measurement in which an ion generated from the target component is selected as the target ion is performed to create an extracted ion chromatogram. In the target analysis, the peak detection only needs to be performed on the waveform within a limited range of time (e.g., a waveform including a peak portion of 1.5 minutes long) corresponding to the retention time of the target component within the entire measurement period of the chromatograph, regardless of the kind of target component (for example, see Non Patent Literature 3). Since the SIM or MRM measurement has a high degree of selectivity for the target component, a narrow, sharp peak can be obtained. For the detection of a peak from these types of waveforms, the waveform-analyzing technique described in Patent Literature 1 can be suitably used.

In contrast, in the case of an exhaustive analysis of unknown components contained in a sample (“non-target analysis”), the peak detection must be performed on the waveform covering the entire measurement period of the chromatograph (e.g., more than 60 minutes) since the position at which a peak will appear (retention time) is unknown. In addition, when a PDA detector or UV detector is used as the detector in the chromatograph, the resulting peaks may considerably vary in width; the period of time from the peak-beginning point to the peak-ending point may be short (e.g., with a peak width of approximately 0.5 minutes) or long (e.g., with a peak width that exceeds 5 minutes), as shown in Non Patent Literature 4 for example. The present inventor applied the waveform-analyzing technique described in Patent Literature 1 to this type of chromatogram and found that there were cases in which the peak could not be correctly detected.

Although the examples described so far have been concerned with the case of detecting a peak from a chromatogram acquired by a chromatograph, a similar problem also occurs in the case of detecting a peak from other types of waveforms.

The problem to be solved by the present invention is to provide a technique which enables the correct detection of peaks having various widths in a waveform acquired by a measurement of a sample using an analyzer.

### Solution to Problem

One mode of the present invention developed for solving the previously described problem is a waveform-analyzing method for analyzing a waveform formed by analysis-target data acquired by a measurement of a sample using an analyzer, the waveform having a first parameter on a horizontal axis and a second parameter on a vertical axis, the waveform-analyzing method including:
a first-trained-model construction step for constructing a first trained model by machine learning in which first reference waveform data forming a first reference waveform having the first parameter on the horizontal axis and the second parameter on the vertical axis is used as teaching data, the first reference waveform having a peak portion including a known combination of a value of the first parameter and a value of the second parameter, the first trained model being configured so that when a first window is applied on the horizontal axis for extracting a predetermined range of data from the first reference waveform data and an input of first partial data corresponding to the first window is received, the first trained model outputs a first index in response to the input, the first index representing a peak portion or a non-peak portion for each of a plurality of first-partial-data elements constituting the first partial data;
a second-trained-model construction step for constructing a second trained model by machine learning in which second reference waveform data forming a second reference waveform having the first parameter on the horizontal axis and the second parameter on the vertical axis is used as teaching data, the second reference waveform having a peak portion including a known combination of a value of the first parameter and a value of the second parameter, the second trained model being configured so that when a second window is applied on the horizontal axis for extracting a predetermined range of data from the second reference waveform data, the second window having a different width from the first window, and an input of second partial data corresponding to the second window is received, the second trained model outputs a second index in response to the input, the second index representing a peak portion or a non-peak portion for each of a plurality of second-partial-data elements constituting the second partial data;
a first-index output step for extracting first analysis-target partial data corresponding to the first window from the analysis-target data, and inputting the first analysis-target partial data into the first trained model to obtain an output of the first index for each of a plurality of first analysis-target-data elements constituting the first analysis-target partial data;
a second-index output step for extracting second analysis-target partial data corresponding to the second window from the analysis-target data, and inputting the second analysis-target partial data into the second trained model to obtain an output of the second index for each of a plurality of second analysis-target-data elements constituting the second analysis-target partial data; and
a peak portion estimation step for estimating a peak portion from the analysis-target data, based on the first index obtained as the output in the first-index output step and the second index obtained as the output in the second-index output step.

Another mode of the present invention developed for solving the previously described problem is a waveform-analyzing device used for analyzing a waveform formed by analysis-target data acquired by a measurement of a sample using an analyzer, the waveform having a first parameter on a horizontal axis and a second parameter on a vertical axis, the waveform-analyzing device including:
a first-trained-model storage section in which a first trained model is stored, the first trained model being constructed by machine learning in which first reference waveform data forming a first reference waveform having the first parameter on the horizontal axis and the second parameter on the vertical axis is used as teaching data, the first reference waveform having a peak portion including a known combination of a value of the first parameter and a value of the second parameter, and the first trained model being configured so that when a first window is applied on the horizontal axis for extracting a predetermined range of data from the first reference waveform data and an input of first partial data corresponding to the first window is received, the first trained model outputs a first index in response to the input, the first index representing a peak portion or a non-peak portion for each of a plurality of first-partial-data elements constituting the first partial data;
a second-trained-model storage section in which a second trained model is stored, the second trained model being constructed by machine learning in which second reference waveform data forming a second reference waveform having the first parameter on the horizontal axis and the second parameter on the vertical axis is used as teaching data, the second reference waveform having a peak portion including a known combination of a value of the first parameter and a value of the second parameter, and the second trained model being configured so that when a second window is applied on the horizontal axis for extracting a predetermined range of data from the second reference waveform data, the second window having a different width from the first window, and an input of second partial data corresponding to the second window is received, the second trained model outputs a second index in response to the input, the second index representing a peak portion or a non-peak portion for each of a plurality of second-partial-data elements constituting the second partial data;
a first-index output processor configured to extract first analysis-target partial data corresponding to the first window from the analysis-target data, and to input the first analysis-target partial data into the first trained model to obtain an output of the first index for each of a plurality of first analysis-target-data elements constituting the first analysis-target partial data;
a second-index output processor configured to extract second analysis-target partial data corresponding to the second window from the analysis-target data, and to input the second analysis-target partial data into the second trained model to obtain an output of the second index for each of a plurality of second analysis-target-data elements constituting the second analysis-target partial data; and
a peak portion estimator configured to estimate a peak portion from the analysis-target data, based on the first index obtained as the output from the first-index output processor and the second index obtained as the output from the second-index output processor.

### Advantageous Effects of Invention

The present inventor has conceived the idea of the present invention from the finding that, in order to correctly detect a peak portion in a set of waveform data, it is necessary to analyze the entirety of each peak as well as analyze a sufficient number of points of measurement data to estimate the peak portion.

Applying the first window (or second window) on the horizontal axis for extracting a predetermined range of data from the reference waveform data (or analysis-target data) means the process of applying the first window (or second window) having a predetermined width in the direction of the horizontal axis to the reference waveform data (or analysis-target data) to extract partial data located within the first window (or second window). This process is normally performed a plurality of times from the beginning position toward the ending position of the reference waveform data or analysis-target data, with the first or second window gradually shifted in the direction of the horizontal axis (“sliding window”) so that the neighboring windows overlap each other. The process of estimating a peak portion based on the first and second indices means the process in which a peak portion is estimated, for example, based on the index representing a peak portion being outputted for a series of first or second analysis-target-data elements arranged in the direction of the horizontal axis. By performing those estimating processes on the entire set of the analysis-target data forming the waveform to be analyzed, the peak portions and the non-peak portions in the waveform data can be estimated.

In the present invention, when the machine learning using, as teaching data, reference waveform data with the position of the peak portion previously known is performed, not only the first trained model is construct by machine learning in which the first window for extracting a predetermined range of data in the direction of the horizontal axis is applied, but the second trained model is also constructed by machine learning in which the second window for extracting a predetermined range of data is applied, where the second window has a different width from the first window. The analysis-target data is fed into both the first and second trained models to obtain outputs of the indices representing a peak portion or a non-peak portion from each model (first and second indices). In this manner, the present invention employs the first trained model using the first window and the second trained model using the second window having a different width from the first window. The use of the second trained model which is suited for detecting a peak having a different width from the first trained model makes it possible to use the first window for detecting a peak that cannot be detected with the second window, and to use the second window for detecting a peak that cannot be detected with the first window, so as to estimate the positions of peaks having different widths and correctly detect those peaks.

### BRIEF DESCRIPTION OF DRAWINGS

FIG. 1 is a configuration diagram of the main components of a liquid chromatograph system including one embodiment of the waveform-analyzing device according to the present invention.

FIG. 2 is a table showing the relationship between the sampling rate in a PDA detector and the half-value width of a peak for which the sampling rate concerned can be suitably used as a measurement condition.

FIG. 3 is a table showing the relationship between the sampling rate and the time constant in a PDA detector.

FIG. 4 is a flowchart of the procedure for creating a trained model in one embodiment of the waveform-analyzing method according to the present invention.

FIG. 5 is a table showing the relationship of the sampling rate, half-value width of the peak, range that can be considered to be a peak portion when the peak is approximated by a Gaussian function, and width of the window.

FIG. 6 is a diagram illustrating situations in which the first window, second window and third window are respectively applied to teaching data.

FIG. 7 is a flowchart of the procedure for estimating a peak portion included in unanalyzed chromatogram data in one embodiment of the waveform-analyzing method according to the present invention.

### DESCRIPTION OF EMBODIMENTS

An embodiment of the waveform-analyzing method and the waveform-analyzing device according to the present invention is hereinafter described with reference to the drawings.

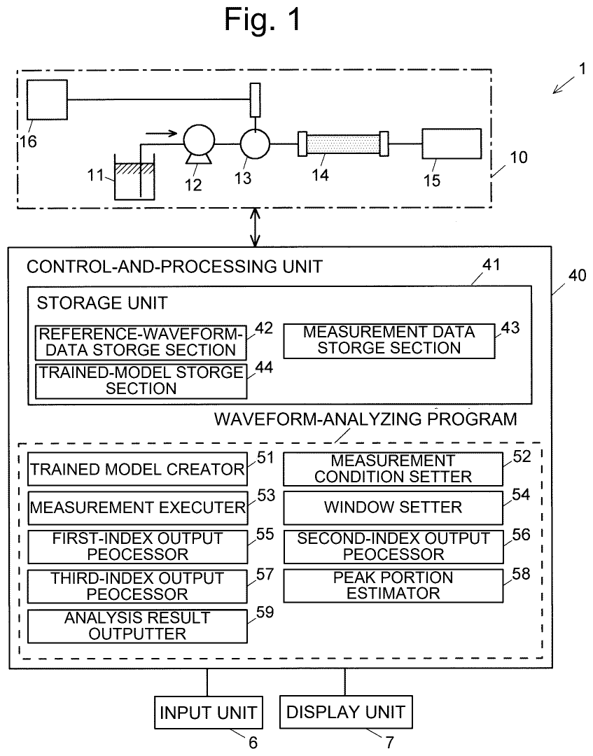

FIG. 1 shows the configuration of the main components of a liquid chromatograph system 1 including the waveform-analyzing device according to the present embodiment. The liquid chromatograph system 1 includes a liquid chromatograph unit 10 and a control-and-processing unit 40. A portion of the control-and-processing unit 40 corresponds to the waveform-analyzing device according to the present invention. A chromatograph waveform (chromatogram) obtained from a liquid chromatograph system or gas chromatograph system normally consists of a set of data with the horizontal axis representing time and the vertical axis representing detection intensity. It should be noted that the waveform to be analyzed in the present invention is not limited to chromatograms as in the present embodiment; for example, it may also be a spectrum waveform.

The liquid chromatograph unit 10 includes a mobile phase container 11 in which a mobile phase is contained, a liquid-supply pump 12 for supplying a mobile phase from the mobile phase container 11, an injector 13 for injecting a liquid sample, a column 14 for separating components contained in the liquid sample, and a detector 15 for detecting the components sequentially exiting from the column 14. The unit also includes an autosampler 16 in which sample containers holding a plurality of liquid samples are set, and which is configured to sequentially introduce those liquid samples into the injector 13 in a specific order described in the measurement conditions. As for the detector 15, a suitable type of detector for the components to be detected is used, such as a mass analyzer, ultraviolet absorbance detector (UV detector), photodiode array detector (PDA detector), differential refractive index detector (RID) or electric conductivity detector.

The control-and-processing unit 40 includes a storage unit 41. The storage unit 41 has a reference-waveform-data storage section 42, measurement-data storage section 43, and trained-model storage section 44. The reference-waveform-data storage section 42 holds “reference waveform data”, which are measurement data acquired by measurements using a mass analyzer, ultraviolet absorbance detector (UV detector), photodiode array detector (PDA detector), differential refractive index detector (RID), electric conductivity detector and other types of devices as the detector 15, and on which the peak detection and other kinds of processing have already been performed, along with the related information, such as the measurement conditions (including the sampling rate) and the type of detector.

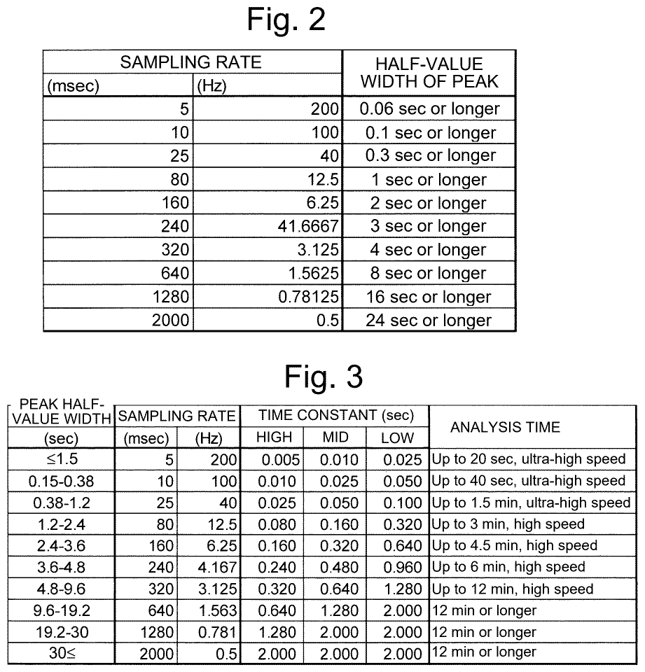

As one example, FIG. 2 shows the relationship between the sampling rate in a PDA detector (SPD-M 10A vp/M 20A/M 30A/30A M/M 40, manufactured by Shimadzu Corporation) and the half-value width of the peak that can be correctly detected by using that sampling rate. To correctly detect a peak means to form the peak from a sufficient number of measurement points so as to correctly represent its shape. For example, when the sampling rate is 5 msec, the shape of a peak having a half-value width equal to or greater than 0.06 sec can be correctly represented. In addition, FIG. 3 shows the relationship between the sampling rate and the time constant in some of the aforementioned devices (SPD-M 30A and SPD-M 40).

In many cases, an analysis result is provided to a user in the form of a waveform on a display screen. Although the waveform provided to the user is a two-dimensional figure, the data constituting that figure is a series of numerical information obtained by converting detector signals into a digital form. For example, in normal cases, the reference waveform data used for machine learning is two-dimensional data in which the values of output signals from the detector are arranged in time series. Since the time-series information, i.e., the sampling interval, is previously known, the reference waveform can be reproduced even without the time-series information. Therefore, the reference waveform data may be one-dimensional data. As long as the time interval of the sampling is previously known, the time-series data can be restored by sequentially arranging the pieces of data at the time intervals of the sampling. In many cases, the time interval of the sampling is included in the measurement conditions and is therefore a piece of known information. The reference waveform data is prepared for use in machine learning, and the data elements which constitute the peak portion included in this data are already identified. Reference waveform data includes a plurality of sets of chromatogram data acquired using the same measurement conditions and the same type of analyzer or detector. Those sets of reference waveform data may be previously obtained by measurements using the liquid chromatograph system 1 according to the present embodiment, or they may alternatively be retrieved from a database holding a collection of data obtained by measurements using a device different from the liquid chromatograph system 1 according to the present embodiment. The reference waveform data to be used in machine learning should preferably have the same data structure as the analysis-target data to be processed for data analysis. The measurement-data storage section 43 may additionally hold measurement conditions to be used for performing measurements of various compounds. Furthermore, the measurement-data storage section 43 is used to sequentially store chromatogram data acquired by the liquid chromatograph unit 10. The trained-model storage section 44 holds a first trained model, second trained model and third trained model created by a trained model creator 51 (which will be described later).

The control-and-processing unit 40 includes, as its functional blocks, a trained model creator 51, measurement condition setter 52, measurement executer 53, window setter 54, first-index output processor 55, second-index output processor 56, third-index output processor 57, peak portion estimator 58 and analysis result outputter 59. It should be noted that the liquid chromatograph system 1 may be prepared as a package for customers from which the does not include the trained model creator 51. In that case, the trained models should be created by the developer using the trained model creator 51 and stored in the trained-model storage section 44 before the system is delivered to the customer. In this case, the trained model creator 51 may be excluded from the liquid chromatograph system 1. The control-and-processing unit 40 is actually a generally used personal computer, on which the aforementioned functional blocks are embodied by executing a pre-installed waveform-analyzing program on the processor of the computer. Additionally, an input unit 6 consisting of a keyboard, mouse and other devices, as well as a display unit 7 consisting of a liquid crystal display and other devices, are connected to the control-and-processing unit 40.

Next, a method for analyzing a chromatogram using the chromatograph mass spectrometry system according to the present embodiment is described. In the chromatograph mass spectrometry system according to the present embodiment, when the waveform-analyzing program is executed, a screen for selecting either the creation of a trained model or the analysis of chromatogram data is shown on the display unit 7.

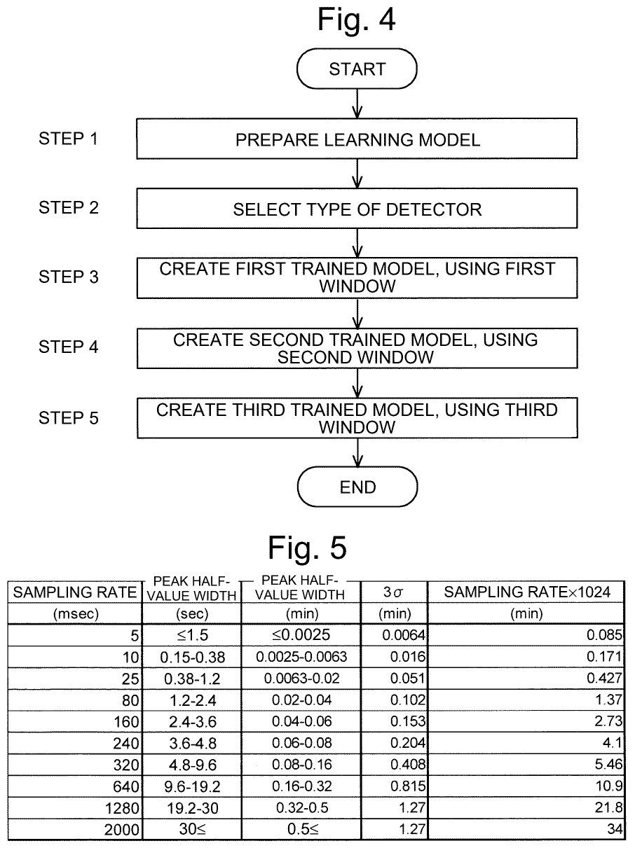

Initially, the procedure for creating a trained model is described with reference to the flowchart in FIG. 4.

When the creation of a trained model is selected, the trained model creator 51 prepares an untrained learning model (Step 1). As for this leaning model, various types of models capable of performing semantic segmentation can be suitably used. Semantic segmentation is generally used for analyzing images consisting of two-dimensionally distributed pixel data. However, in the present embodiment, the technique is applied in an analysis of the waveform data of a chromatogram consisting of a plurality of data elements obtained at predetermined sampling intervals. Examples of the learning models available for performing semantic segmentation include U-Net, SeGNet and PSPNet (for example, see Patent Literature 1). In the present embodiment, U-Net is used as the learning model.

Subsequently, the trained model creator 51 shows, on the display unit 7, a screen which allows the user to specify the kind of teaching data to be read from the reference-waveform-data storage section 42. For example, a screen which allows the user to select the type of detector from a drop-down list may be used as this screen. As noted earlier, the reference-waveform-data storage section 42 holds reference waveform data which were acquired by measurements using a mass analyzer, ultraviolet absorbance detector (UV detector), photodiode array detector (PDA detector), differential refractive index detector (RID), electric conductivity detector and other types of devices, and on which the peak detection and other kinds of processing have already been performed, along with the related information, such as the type of detector.

When the type of detector is selected (Step 2), the trained model creator 51 reads, from the reference-waveform-data storage section 42, a plurality of sets of reference waveform data acquired by using the selected detector. When reading the reference waveform data, the trained model creator 51 may additionally read the information of the sampling rate from the reference-waveform-data storage section 42.

The number of data points to be fed into the learning model may be arbitrarily determined. However, inputting a large number of data points leads to a long period of time required for the processing. Therefore, it is preferable to select a suitable number of points for the hardware power (processing capacity). On the other hand, too small a number of data points means that the machine learning will be performed based on information from which the waveform to be analyzed cannot be reproduced with a sufficient level of accuracy, as is explained in the sampling theorem (or the like), and a trained model which estimates the peak portion based on that machine learning will be constructed. In the present embodiment, the number of data points to be fed into the U-Net is 1,024. A total of 1,024 points of measurement data elements extracted at regular intervals from the beginning (i.e., the end closer to the origin of the measurement time on the horizontal axis; the same applies hereinafter) in the reference waveform data are handled as one set and fed into the U-Net to train the learning model. The frame (or range) for extracting one set of measurement data from the reference waveform data in this manner is called the “window”. Accordingly, if the width of this window in the time-axis direction is small, the 1,024 points of data elements will be extracted at short intervals of time within the narrow range of time. Conversely, if the width of the window in the time-axis direction is large, the 1,024 points of data elements will be extracted at long intervals of time within a wide range of time. From the point of view of the reproducibility of the waveform, the interval of time of the data elements should be as small as possible. However, the present inventor has discovered that it is appropriate that the width of the “first window”, which is the window having the smallest width in the time-axis direction, should be equal to 1,024 times the sampling rate of the detector. The reason is because, even when the number of points of the data elements to be fed into the leaning model is set to be larger than the sampling rate of the detector (i.e., even when the interval of time of the data elements is shorter than the sampling rate of the detector), the number of points of data that can actually be acquired from the detector cannot exceed the sampling performance of the detector. FIG. 5 shows the relationship of the sampling rate, half-value width of the peak, range that can be considered to be a peak portion when the peak is approximated by a Gaussian function (±3σ), and length of the window (sampling interval×1,024). Thus, the smallest window size, or the smallest interval of time between the data elements to be fed into the learning model, should preferably be determined based on the sampling rate of the detector. It is also possible to previously store, in the storage unit, the window size or the smallest interval of the input points suited for the detector.

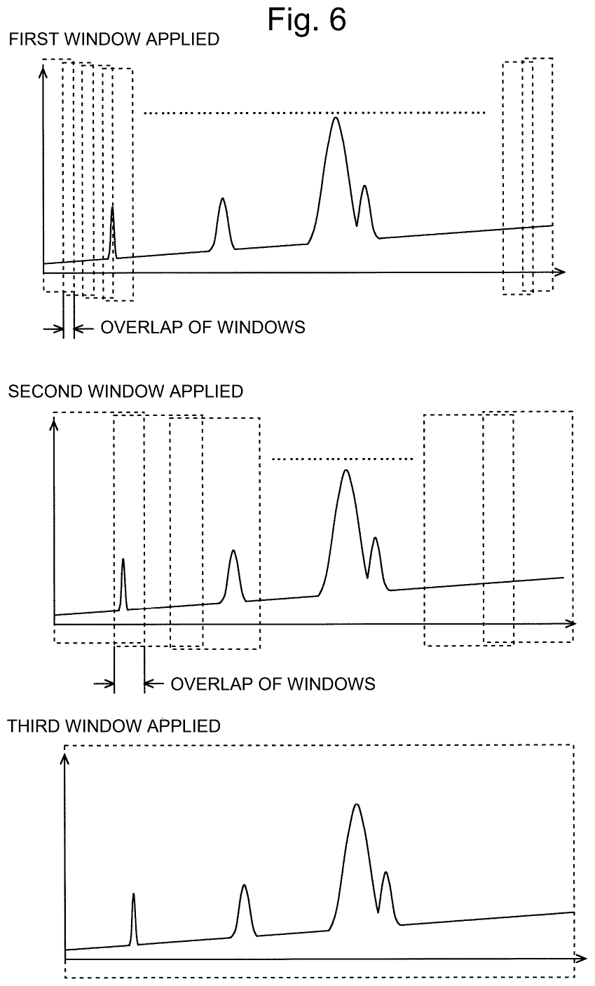

The trained model creator 51 trains the learning model by machine learning using the entire range of the reference waveform data by gradually shifting the position of the first window (“sliding window”) so that the new window overlaps the previous window by a predetermined width in the time-axis direction, as schematically shown in the upper section of FIG. 6. The process of the sliding window should preferably be performed by shifting the window so that the neighboring windows overlap each other by a width corresponding to one third to one half of the width of the window. By this method, almost all peaks appearing in a chromatogram can be covered by the windows in such a manner that each peak is included in one window. Although distinguishing between a peak portion and a non-peak portion is possible even when a portion of the peak is located outside the window, setting the window to include the entire peak can improve the identification accuracy of the peak. For ease of understanding, the reference waveform in FIG. 6 with the window applied is shown in the form of a two-dimensional graph with the horizontal axis representing time and the vertical axis representing detection intensity. However, the reference waveform data forming the reference waveform is actually a sequence of intensity information arranged in time-series in order of sampling; it may be in the form of one-dimensional data which does not explicitly include the information of sampling order or time series (i.e., which has no value in the time-axis direction). In this case, the window may also be a one-dimensional quantity which only defines the length (number of data points) and does not have the information in either the horizontal or vertical axis. Depending on the selection of the window width, a single window can include the entire reference waveform data, as in the case of the third window (which will be described later).

In this manner, the machine learning in which the first window is applied is performed on all sets of reference waveform data (Step 3). This machine learning produces a trained model which receives an input of measurement data and outputs a label (index) representing the property of each data element constituting the measurement data. Examples of the label to be obtained as the output include the peak-beginning point, peak-ending point, single peak, tailing processing peak, complete separation peak, vertical partitioning peak and non-peak portion, as described in Patent Literature 1. The labels other than the non-peak portion are given to a peak portion. The tailing processing peak, complete separation peak and vertical partitioning peak are labels to be given to a portion with two or more peaks overlapping each other (“overlap peak portion”); the output label shows what technique is suited for separating those peaks. It should be noted that those labels are mere examples in a preferable mode; the minimum requirement in the present invention is to output labels (indices) which enable the discrimination between peak portions and non-peak portions. The procedure for performing machine learning as well as the contents of the labels are identical to those described in Patent Literature 1, and therefore, their detailed descriptions will be omitted.

The trained model creator 51 subsequently performs machine learning for all sets of reference waveform data in a similar manner to the previously described case, applying a second window having a different width from the first window (Step 4). In the present embodiment, since the first window is defined with the smallest possible width in the time-axis direction, the second window may be defined with any width larger than the first window.

As noted earlier, various types of detectors are used for liquid chromatographs depending on the component to be detected, such as a mass analyzer, ultraviolet absorbance detector (UV detector), photodiode array detector (PDA detector), differential refractive index detector (RID) and electric conductivity detector. The shape and width of a peak which appears in a chromatogram vary depending on the type of detector. Each type of detector has a specific tendency in the shape of the detected peak. This fact is used in the present embodiment; the width of the second window is determined for each type of detector so that a peak whose peak width is the largest among all possible peaks for that type of detector will be entirely included in one window.

For example, when the detector is a mass analyzer, the largest possible width of the peak is approximately 1.5 minutes, whereas a peak having a width of five or ten minutes may possibly appear when a PDA detector or UV detector is used. Accordingly, the width of the second window is determined beforehand for each type of detector, as noted earlier. For example, when the detector is a mass analyzer, the width of the second window may be previously set to 3 minutes. For a PDA detector or UV detector, the width of the second window may be previously set to 15 minutes. The width of the second window is, for example, 1.5 to 2 times the largest possible width of the peak. When the process of the sliding window is performed as schematically shown in the middle section of FIG. 6, the window may be shifted so that the neighboring windows overlap each other by one third to one half of their width.

When the second window is used, the measurement data which is present within the second window is divided into 1,024 points at regular intervals and fed into the learning model. It should be noted that this is a mere example and does not limit the present invention; when the second window is used, the number of points of the measurement data present within the second window may be adjusted to 1,024 by a preparative computation, e.g., by totaling or averaging a plurality of points of measurement data or thinning the measurement data, before the points of data are fed into the U-Net for the machine learning.

The trained model creator 51 further performs machine learning for all sets of reference waveform data in a similar manner to the previously described case, applying a third window having a width which corresponds to the entire measurement period (Step 5).

In a liquid chromatograph, a gradient analysis may be performed in which the mixture ratio of a plurality of mobile phases is gradually changed during the measurement. A gradient analysis is often accompanied by the so-called “drift”, i.e., a gradual increase (or decrease) of the baseline throughout the entire period of the measurement. A trained model that can correctly discriminate between a drift and a peak cannot be easily obtained by machine learning which uses only a portion of the reference waveform data as in the case of the first or second window. Accordingly, in the present embodiment, as schematically shown in the lower section of FIG. 6, the machine learning in which a third window corresponding to the entire period of the measurement is applied is performed. In the case of using the third window, the number of points of the measurement data present within the third window is larger than that of the data points to be fed into the U-Net. Accordingly, in the case of using the third window, as in the previously described case, the number of points of the measurement data present within the third window is adjusted to 1,024 by a preparative computation, e.g., by increasing the interval of the input points, averaging a plurality of pieces of measurement data or thinning the measurement data, before the points of data are fed into the U-Net for the machine learning.

By performing the processing described so far, the trained model creator 51 stores the first trained model which uses the first window determined according to the sampling interval, and the second trained model which uses the second window determined according to the type of detector, in the trained-model storage section 44. Furthermore, the trained model creator 51 constructs a third trained model which uses the third window having a width corresponding to the entire measurement period and stores this model in the trained-model storage section 44 along with the information of the corresponding type of detector. In the case where the second window has a width corresponding to the entire measurement period, it is unnecessary to construct and store the third trained model since the second and third windows are identical to each other.

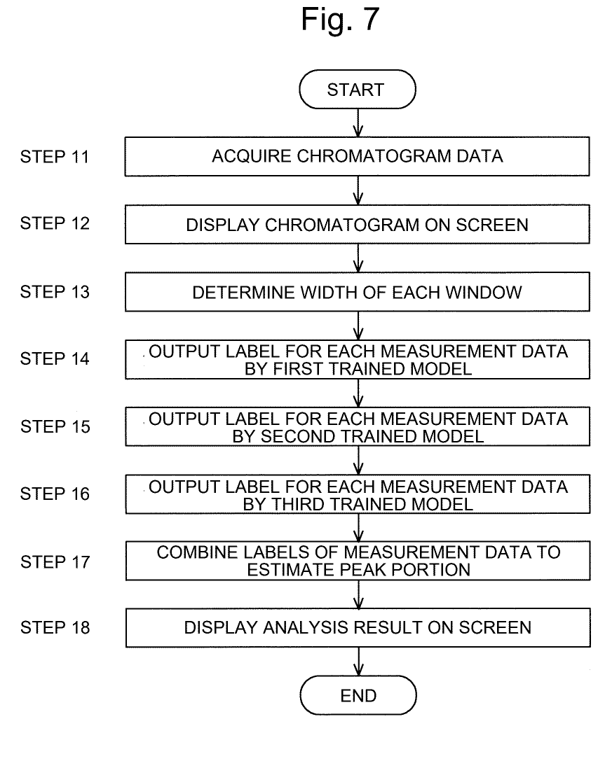

Next, the procedure for analyzing the waveform of an unanalyzed chromatogram is described with reference to the flowchart in FIG. 7.

A user sets samples in the autosampler 16 and issues a command to initiate the analysis. Then, the measurement condition setter 52 reads the measurement conditions stored in the measurement-data storage section 43 and shows them on the screen of the display unit 7. These measurement conditions include the type of detector to be used for the measurement and the information of the sampling rate of the detector. After selecting the measurement condition to be used from the displayed options (and making appropriate modifications as needed), the user issues a command to initiate the measurement. Then, the measurement condition setter 52 creates a batch file for carrying out the measurement under the selected condition and saves it in the measurement-data storage section 43.

When the command to execute the measurement is issued by the user, the measurement executer 53 performs a chromatographic analysis of a sample by executing the batch file saved in the measurement-data storage section 43 so as to acquire measurement data forming a chromatogram and save the data in the measurement-data storage section 43. As with the reference waveform data, this measurement data is a sequence of data in which output signals from the detector are arranged in time series. This data corresponds to the analysis-target data in the present invention. Although the present example assumes that a set of chromatogram data is newly acquired by a measurement of a sample performed by the measurement executer 53, the acquisition of chromatogram data may be achieved in a different way, e.g., by retrieving a set of previously acquired chromatogram data.

After the chromatogram data has been acquired by performing a measurement of a sample or retrieving already acquired data (Step 11), the user issues a command to analyze the chromatogram data. Then, the window setter 54 creates a chromatogram from the read data and displays it on the screen of the display unit 7 (Step 12). Additionally, the window setter 54 determines the values of the widths of the first, second and third windows based on the sampling rate, type of detector and entire measurement period described in the measurement conditions and shows those values on the display unit 7. The width of the first window is the sampling rate multiplied by 1,024, that of the second window is a value related to the type of detector, and that of the third window is the entire measurement period. The user checks the values of those windows shown on the display unit 7 and performs a predetermined input operation to confirm those values (Step 13). The window size to be used for the estimation should preferably be equal to the window size used in machine learning, although the present invention is not limited to this. For example, even when there is a difference between the size of the window applied to the reference waveform data in the machine learning process and that of the window applied to the waveform data to be analyzed in the estimation process, the influence on the estimation accuracy will be insignificant if that difference in size is small. Furthermore, the influence can be further reduced by adding a preliminary normalization process.

After the widths of the windows have been determined, the first-index output processor 55 reads 1,024 points of measurement data from the beginning of the chromatogram data and inputs them into the first trained model. Once again, the window is gradually shifted so that the neighboring windows overlap each other by one third to one half of their width. For each of the inputted chromatogram data elements, the first trained model outputs one of the labels of the peak beginning point, peak-ending point, single peak, tailing processing peak, complete separation peak, vertical partitioning peak and non-peak portion (Step 14). In the present embodiment, the label is outputted for each of the data elements arranged along the time axis. Although the input data in the present embodiment is one-dimensional data consisting of only the detection intensities arranged in time series, the time-series information corresponding to each detection intensity (the information of the point in time at which the data of each detection intensity was acquired) is reproduced when the label is given to each data element. The label outputted in this step corresponds to the first index representing a peak portion or a non-peak portion in the present invention. More specifically, only the label representing the non-peak portion corresponds to the “index representing a non-peak portion”; all the other labels correspond to the “index representing a peak portion”. The steps of shifting the first window so that the neighboring windows overlap each other and inputting 1,024 points of data elements to obtain an output of the label for each data element are repeatedly performed throughout the entire measurement range. Consequently, one or more labels are outputted for each of all measurement data elements (a plurality of labels are outputted for measurement data located within the overlapping portion of the windows).

Next, the second-index output processor 56 performs the process of reducing the number of data points included within the second window applied to the chromatogram to 1,024 points. Specifically, the process may include increasing the time interval of the data points to be extracted from a plurality of pieces of measurement data, totaling those data, averaging those data or thinning the measurement data, as in the case where the second window was applied to the teaching data. Then, the second-index output processor 56 reads 1,024 points of measurement data from the beginning of the chromatogram data and inputs them into the second trained model. For each of the inputted measurement data elements, the second trained model outputs one of the labels of the peak beginning point, peak-ending point, single peak, tailing processing peak, complete separation peak, vertical partitioning peak and non-peak portion. The steps of shifting the second window so that the neighboring windows overlap each other and inputting 1,024 points of data elements to obtain an output of the label for each data element are repeatedly performed throughout the entire measurement range. Consequently, one or more labels are outputted for each of all measurement data elements (Step 15). Once again, a plurality of labels are outputted for measurement data located within the overlapping portion of the windows. Since the width of the first window in the present embodiment is smaller than that of the second window, a narrow peak that will be overlooked by the second window (i.e., the second trained model) can be detected by the first window (i.e., the first trained model). Conversely, a broad peak that cannot be entirely covered by the first window and therefore cannot be accurately detected by the first window can be accurately detected by the second window.

Furthermore, the third-index output processor 57 performs the process of reducing all measurement points to 1,024 points. Specifically, the process may include increasing the time interval of the data points to be extracted from a plurality of pieces of measurement data, totaling those data, averaging those data or thinning the measurement data, as in the case where the third window was applied to the teaching data. Then, the third-index output processor 57 inputs the 1,024 points of measurement data into the third trained model. For each of the inputted measurement data elements, the third trained model outputs one of the labels of the peak beginning point, peak-ending point, single peak, tailing processing peak, complete separation peak, vertical partitioning peak and non-peak portion. Thus, one label is outputted for each of all measurement data elements (Step 16).

After the process in which all windows are applied to the target chromatogram data has been completed, the peak portion estimator 58 determines the label of each measurement data element. If there is a measurement data element (measurement point) for which a plurality of labels have been outputted, the peak portion estimator 58 combines those labels. Based on the labels of the measurement data elements, the peak portion estimator 58 estimates the peak portion (Step 17). If there is a measurement data element for which different labels have been outputted, the peak portion estimator 58 selects one label for that measurement data element (measurement point) based on a previously determined order of priority. Specifically, for example, if one label representing a peak portion and another label representing a non-peak portion are outputted for the same data element, a priority is given to the peak portion. As for the single peak and the overlap peak (tailing processing peak, complete separation peak, or vertical partitioning peak), a priority is given to the overlap peak. These rules prevent the situation in which the presence of a peak is overlooked, or the situation in which an overlap peak that requires peak separation is incorrectly estimated as a single peak.

Ultimately, the analysis result outputter 59 displays, on the display unit 7, the analysis result (the labels given to the respective measurement data elements) along with the chromatogram being analyzed (Step 18). This allows the user to visually recognize a peak which is considered to be present in the chromatogram being analyzed.

In the case of analyzing a known kind of target component contained in a sample (“target analysis”), a mass analyzer is used as the detector, for example, and an SIM or MRM measurement in which an ion generated from the target component is selected as the target ion is performed to create an extracted ion chromatogram. In the target analysis, the peak detection only needs to be performed on the waveform within a limited range of time (e.g., 1.5 minutes long) corresponding to the retention time of the target component within the entire measurement period of the chromatograph (for example, see Non Patent Literature 3). Since the SIM or MRM measurement has a high degree of selectivity for the target component, a narrow, sharp peak can be obtained. The waveform-analyzing technique described in Patent Literature 1 was developed on the assumption of detecting a peak from such a waveform.

In contrast, in the case of an exhaustive analysis of unknown components contained in a sample (“non-target analysis”), the peak detection must be performed on the data of the waveform over the entire measurement period of the chromatograph (e.g., more than 60 minutes) since the position at which a peak will appear (retention time) is unknown. In addition, when a PDA detector or UV detector is used as the detector in the chromatograph, the resulting peaks may considerably vary in width; the period of time from the peak-beginning point to the peak-ending point may be short (e.g., with a peak width of approximately 0.5 minutes) or long (e.g., with a peak width that exceeds 5 minutes), as shown in Non Patent Literature 4 for example.

In this situation, setting a window within which a sufficient number of measurement points for a narrow peak are allotted causes the problem that, although that narrow peak can be correctly detected, a broader peak cannot be entirely covered by the single window, and therefore, it may be difficult to correctly detect the peak portion by the trained model. On the other hand, setting a window within which a sufficient number of measurement points for a broad peak are allotted causes the problem that, although that broad peak can be correctly detected, the number of input data assigned to a narrow peak will be fewer (e.g., only one or two points), and therefore, the narrow peak may not be detected. As noted earlier, the number of sampling points assigned to the window is fixed (in the present embodiment, 1,024 points). Therefore, that the window has a large width in the axial direction means that the data elements are extracted at large intervals of time. Therefore, a narrow peak may fall within the range between the two neighboring data points, and in the worst-case scenario, none of the points in the peak will be detected. Furthermore, none of these trained models covers the entire measurement range with a single window, and therefore, cannot correctly detect the general tendency of the fluctuation of the baseline over the entire measurement range, with the possible result that a fluctuation of the baseline is incorrectly identified as a peak, or conversely, a peak is incorrectly identified as the baseline (or non-peak portion).

A possible solution to the previously described problems is to prepare measurement data representing a pseudo broad peak by expanding an extremely small peak in the temporal direction (as well as the intensity direction) and use that data for the machine learning of the learning model. However, in that case, the data used for the machine learning will include not only the peak but also the noise level expanded in the temporal direction. Since none of the noise components detected in actual measurements is temporally expanded in this manner, the aforementioned type of machine learning will create a trained model that has learned waveforms that will never occur in actual measurement data. A trained model created in this manner cannot correctly discriminate between non-peak portions (noise components) and peak portions in the analysis-target data acquired by actual measurements.

In contrast, in the present embodiment, as described earlier, the first, second and third trained models are created by three modes of machine learning which respectively use three windows having different widths. This allows for the use of the first trained model which can correctly detect narrow peaks and the second trained model which can correctly detect broad peaks. The third trained model which uses a single window covering the entire measurement range can correctly detect the fluctuating baseline throughout the entire measurement time range and correctly discriminate between a fluctuation of the baseline and a peak.

The previous embodiment is a mere example and can be appropriately changed or modified without departing from the spirit of the present invention.

In the previous embodiment, three trained models were created by machine learning in which three windows with different widths were applied. The number of kinds of windows or that of the trained models may be two as well as four or more.

Although the analysis-target data in the previous embodiment was chromatogram data acquired by a measurement using a liquid chromatograph, the waveform-analyzing method and waveform-analyzing device according to the present invention can be used for analyzing various kinds of data. For example, an analysis similar to the previously described one can be performed on chromatogram data acquired by a measurement using a gas chromatograph, or on measurement data which is not chromatogram data. Furthermore, an analysis similar to the previously described one can also be performed, for example, on optical spectrum data acquired by a measurement using a spectrophotometer (a waveform representing a change in detection intensity with respect to a wavelength or wavenumber axis), or mass spectrum data acquired by a measurement using a mass spectrometer.

In the previous embodiment, the second trained model was constructed by performing machine learning in which the second window having a width previously related to the type of detector was applied to the training data. Another possibility is to create a plurality of trained models for one detector by applying, to the training data, a plurality of windows having different widths, and to save those models in the trained-model storage section 44, with each model associated with the information concerning the width of the window (and the type of detector). In this case, a chromatogram created from the chromatogram data to be analyzed is shown on the display unit 7, on which the user can check the shape of the chromatogram and change the width of the second window. When the width of the second window has been changed by the user, the second-index output processor 56 retrieves, from the trained-model storage section 44, a second trained model corresponding to the width of the second window after the change, and outputs a label for each measurement data element in the previously described manner. Additionally, when there is no drift or similar fluctuation of the baseline over the entire measurement period in the chromatogram being analyzed, the estimation of the peak portion may be performed without using the third window.

The previously described configuration may be altered to allow the user to enter an expected value of the peak width instead of changing the width of the window. In this case, the value obtained by multiplying the entered peak width by a previously determined constant (e.g., 1.5 or 2) can be used as the width of the second window for performing the processing in the previously described manner.

In the previous embodiment, U-Net was used for all of the first, second and third trained models. It is also possible to use a different type of model for each trained model. For those trained models, neural networks can be suitably used, in which various kinds of architectures are included, such as an architecture which performs semantic segmentation, one which performs object detection (SSD), one which uses a regression model, a recurrent neural network (RNN), and a transformer. Since these architectures have their respective advantages and disadvantages, the detection accuracy of the peak portion can be improved by using appropriate types of architecture for constructing the trained models.

In the previous embodiment, one label was outputted for each piece of measurement data and the analysis result was shown on the display unit 7. Depending on the architecture which constitutes the model, the trained model may possibly output a plurality of labels and their respective degrees of certainty as the inferred result for one measurement data element. The U-Net described in the previous embodiment is also this type of architecture. Only the label having the highest degree of certainty was outputted in the previous embodiment. However, when this type of trained model is used, other labels with their respective degrees of certainty may also be shown on the display unit 7 in addition to the label having the highest degree of certainty. By this method, if the label considered to have the highest degree of certainty has been judged to be incorrect, the user can change to the label having the second highest degree of certainty to more correctly estimate the peak.

### [Modes]

It is evident to a person skilled in the art that the previously described illustrative embodiment is a specific example of the following modes of the present invention.

### (Clause 1)

One mode of the present invention is a waveform-analyzing method for analyzing a waveform formed by analysis-target data acquired by a measurement of a sample using an analyzer, the waveform having a first parameter on a horizontal axis and a second parameter on a vertical axis, the waveform-analyzing method including:
a first-trained-model construction step for constructing a first trained model by machine learning in which first reference waveform data forming a first reference waveform having the first parameter on the horizontal axis and the second parameter on the vertical axis is used as teaching data, the first reference waveform having a peak portion including a known combination of a value of the first parameter and a value of the second parameter, the first trained model being configured so that when a first window is applied on the horizontal axis for extracting a predetermined range of data from the first reference waveform data, and an input of first partial data corresponding to the first window is received, the first trained model outputs a first index in response to the input, the first index representing a peak portion or a non-peak portion for each of a plurality of first-partial-data elements constituting the first partial data;
a second-trained-model construction step for constructing a second trained model by machine learning in which second reference waveform data forming a second reference waveform having the first parameter on the horizontal axis and the second parameter on the vertical axis is used as teaching data, the second reference waveform having a peak portion including a known combination of a value of the first parameter and a value of the second parameter, the second trained model being configured so that when a second window is applied on the horizontal axis for extracting a predetermined range of data from the second reference waveform data, the second window having a different width from the first window, and an input of second partial data corresponding to the second window is received, the second trained model outputs a second index in response to the input, the second index representing a peak portion or a non-peak portion for each of a plurality of second-partial-data elements constituting the second partial data;
a first-index output step for extracting first analysis-target partial data corresponding to the first window from the analysis-target data, and inputting the first analysis-target partial data into the first trained model to obtain an output of the first index for each of a plurality of first analysis-target-data elements constituting the first analysis-target partial data;
a second-index output step for extracting second analysis-target partial data corresponding to the second window from the analysis-target data, and inputting the second analysis-target partial data into the second trained model to obtain an output of the second index for each of a plurality of second analysis-target-data elements constituting the second analysis-target partial data; and
a peak portion estimation step for estimating a peak portion from the analysis-target data, based on the first index obtained as the output in the first-index output step and the second index obtained as the output in the second-index output step.

### (Clause 2)

Another mode of the present invention is a waveform-analyzing device used for analyzing a waveform formed by analysis-target data acquired by a measurement of a sample using an analyzer, the waveform having a first parameter on a horizontal axis and a second parameter on a vertical axis, the waveform-analyzing device including:
a first-trained-model storage section in which a first trained model is stored, the first trained model being constructed by machine learning in which first reference waveform data forming a first reference waveform having the first parameter on the horizontal axis and the second parameter on the vertical axis is used as teaching data, the first reference waveform having a peak portion including a known combination of a value of the first parameter and a value of the second parameter, and the first trained model being configured so that when a first window is applied on the horizontal axis for extracting a predetermined range of data from the first reference waveform data, and an input of first partial data corresponding to the first window is received, the first trained model outputs a first index in response to the input, the first index representing a peak portion or a non-peak portion for each of a plurality of first-partial-data elements constituting the first partial data;
a second-trained-model storage section in which a second trained model is stored, the second trained model being constructed by machine learning in which second reference waveform data forming a second reference waveform having the first parameter on the horizontal axis and the second parameter on the vertical axis is used as teaching data, the second reference waveform having a peak portion including a known combination of a value of the first parameter and a value of the second parameter, and the second trained model being configured so that when a second window is applied on the horizontal axis for extracting a predetermined range of data from the second reference waveform data, the second window having a different width from the first window, and an input of second partial data corresponding to the second window is received, the second trained model outputs a second index in response to the input, the second index representing a peak portion or a non-peak portion for each of a plurality of second-partial-data elements constituting the second partial data;
a first-index output processor configured to extract first analysis-target partial data corresponding to the first window from the analysis-target data, and to input the first analysis-target partial data into the first trained model to obtain an output of the first index for each of a plurality of first analysis-target-data elements constituting the first analysis-target partial data;
a second-index output processor configured to extract second analysis-target partial data corresponding to the second window from the analysis-target data, and to input the second analysis-target partial data into the second trained model to obtain an output of the second index for each of a plurality of second analysis-target-data elements constituting the second analysis-target partial data; and
a peak portion estimator configured to estimate a peak portion from the analysis-target data, based on the first index obtained as the output from the first-index output processor and the second index obtained as the output from the second-index output processor.

The present inventor has found that, in order to correctly detect a peak portion in a set of waveform data, it is necessary to analyze the entirety of each peak as well as analyze a sufficient number of points of measurement data to estimate the peak portion.

Applying the first window (or second window) to the reference waveform data (or analysis-target data) means the process of applying the first window (or second window) having a predetermined width in the direction of the horizontal axis to the reference waveform data (or analysis-target data) to extract partial data located within the first window (or second window). This process is normally performed a plurality of times from the beginning position toward the ending position of the reference waveform data or analysis-target data, with the first or second window gradually shifted in the direction of the horizontal axis (“sliding window”) so that the neighboring windows overlap each other. The process of estimating a peak portion based on the first and second indices means the process in which a peak portion is estimated, for example, based on the index representing a peak portion being outputted for a series of first or second analysis-target-data elements arranged in the direction of the horizontal axis. By performing those estimating processes on the entire set of the analysis-target data forming the waveform to be analyzed, the peak portions and the non-peak portions in the waveform data can be estimated.

In the waveform-analyzing method according to Clause 1 and the waveform-analyzing device according to Clause 2, when the machine learning using, as teaching data, reference waveform data with the position of the peak portion previously known is performed, not only the first trained model is construct by machine learning in which the first window for extracting a predetermined range of data in the direction of the horizontal axis is applied, but the second trained model is also constructed by machine learning in which the second window for extracting a predetermined range of data is applied, where the second window has a different width from the first window. The first and second reference waveform data may be identical to or different from each other, although it is preferable that the first reference waveform data should include a narrow peak while the second reference waveform data should include a broad peak. The analysis-target data is fed into both the first and second trained models to obtain outputs of the indices representing a peak portion or a non-peak portion from each model (first and second indices). In this manner, the waveform-analyzing method according to Clause 1 and the waveform-analyzing device according to Clause 2 can correctly detect peaks having different widths by employing the first trained model using the first window and the second trained model using the second window having a different width from the first window.

### (Clause 3)

In the waveform-analyzing device according to Clause 3, which is a waveform-analyzing device according to Clause 2, information of the sampling rate in the measurement by which the analysis-target data was acquired is related to the same analysis-target data, and the width of the first window is determined based on the sampling rate.

In the waveform-analyzing device according to Clause 3, the measurement data elements constituting the measurement data can be directly used to estimate the peak portion from the analysis-target data.

### (Clause 4)

In the waveform-analyzing device according to Clause 4, which is a waveform-analyzing device according to Clause 2 or 3, information of the type of detector used in the measurement by which the analysis-target data was acquired is related to the same analysis-target data, and the width of the second window is determined beforehand based on the type of detector.

The width of the peak appearing in the measurement data varies depending on the type of detector used in the measurement of the sample. In the waveform-analyzing device according to Clause 4, the width of the second window is appropriately determined according to the type of detector used in the process of acquiring the analysis-target data so that the peak portion included in the analysis-target data can be correctly detected.

### (Clause 5)

The waveform-analyzing device according to Clause 5, which is a waveform-analyzing device according to according to Clause 2 or 3, the second window is configured to extract the entirety of the analysis-target data.

When a gradient analysis is performed in a liquid chromatograph, or when a temperature-controlled analysis is performed in a gas chromatograph, the so-called “drift” occurs, which is a gradual increase (or decrease) of the baseline throughout the entire period of the measurement. A trained model that can correctly discriminate between a drift and a peak cannot be easily obtained by machine learning which uses only a portion of the reference waveform data. The waveform-analyzing device according to Clause 5 can discriminate between a drift and a peak since the second trained model is constructed by machine learning which uses a window that corresponds to the entire period of the measurement by which the analysis-target data was acquired.

### (Clause 6)

In the waveform-analyzing device according to Clause 6, which is a waveform-analyzing device according to one of Clauses 2-5, the first trained model and the second trained model are constructed using different architectures.

In the waveform-analyzing device according to one of Clauses 2-5, neural networks can be suitably used for constructing the trained models, in which various kinds of architectures are included, such as an architecture which performs semantic segmentation, one which performs object detection (SSD), one which uses a regression model, a recurrent neural network (RNN), and a transformer. In the waveform-analyzing device according to Clause 6, the detection accuracy of the peak portion can be improved by using appropriate types of architecture for constructing the trained models.

### (Clause 7)

In the waveform-analyzing device according to Clause 7, which is a waveform-analyzing device according to one of Clauses 2-6, the peak portion estimator is configured to give priority to an index representing a peak portion in estimating a peak portion from the analysis-target data if an index outputted for one measurement data element by the first-index output processor is different from an index outputted for the same measurement data element by the second-index output processor.

In the waveform-analyzing device according to Clause 7, when an index representing a peak portion and an index representing a non-peak portion are outputted for the same measurement element, a priority is given to the peak portion. Therefore, all peaks included in the analysis-target data can be detected without omission.

### REFERENCE SIGNS LIST

1 . . . Liquid Chromatograph System
10 . . . Liquid Chromatograph Unit
11 . . . Mobile Phase Container
12 . . . Liquid Supply Pump
13 . . . Injector
14 . . . Column
15 . . . Detector
16 . . . Autosampler
40 . . . Control-and-Processing Unit
41 . . . Storage Unit
42 . . . Reference-Waveform-Data Storage Section
43 . . . Measurement-Data Storage Section
44 . . . Trained-Model Storage Section
51 . . . Trained Model Creator
52 . . . Measurement Condition Setter
53 . . . Measurement Executer
54 . . . Window Setter
55 . . . First-Index Output Processor
56 . . . Second-Index Output Processor
57 . . . Third-Index Output Processor
58 . . . Peak Portion Estimator
59 . . . Analysis Result Outputter
6 . . . Input Unit
7 . . . Display Unit

1. A waveform-analyzing method for analyzing a waveform formed by analysis-target data acquired by a measurement of a sample using an analyzer, the waveform having a first parameter on a horizontal axis and a second parameter on a vertical axis, the waveform-analyzing method comprising:
a first-trained-model construction step for constructing a first trained model by machine learning in which first reference waveform data forming a first reference waveform having the first parameter on the horizontal axis and the second parameter on the vertical axis is used as teaching data, the first reference waveform having a peak portion including a known combination of a value of the first parameter and a value of the second parameter, the first trained model being configured so that when a first window is applied on the horizontal axis for extracting a predetermined range of data from the first reference waveform data, and an input of first partial data corresponding to the first window is received, the first trained model outputs a first index in response to the input, the first index representing a peak portion or a non-peak portion for each of a plurality of first-partial-data elements constituting the first partial data;
a second-trained-model construction step for constructing a second trained model by machine learning in which second reference waveform data forming a second reference waveform having the first parameter on the horizontal axis and the second parameter on the vertical axis is used as teaching data, the second reference waveform having a peak portion including a known combination of a value of the first parameter and a value of the second parameter, the second trained model being configured so that when a second window is applied on the horizontal axis for extracting a predetermined range of data from the second reference waveform data, the second window having a different width from the first window, and an input of second partial data corresponding to the second window is received, the second trained model outputs a second index in response to the input, the second index representing a peak portion or a non-peak portion for each of a plurality of second-partial-data elements constituting the second partial data;
a first-index output step for extracting first analysis-target partial data corresponding to the first window from the analysis-target data, and inputting the first analysis-target partial data into the first trained model to obtain an output of the first index for each of a plurality of first analysis-target-data elements constituting the first analysis-target partial data;
a second-index output step for extracting second analysis-target partial data corresponding to the second window from the analysis-target data, and inputting the second analysis-target partial data into the second trained model to obtain an output of the second index for each of a plurality of second analysis-target-data elements constituting the second analysis-target partial data; and
a peak portion estimation step for estimating a peak portion from the analysis-target data, based on the first index obtained as the output in the first-index output step and the second index obtained as the output in the second-index output step.

2. A waveform-analyzing device used for analyzing a waveform formed by analysis-target data acquired by a measurement of a sample using an analyzer, the waveform having a first parameter on a horizontal axis and a second parameter on a vertical axis, the waveform-analyzing device comprising:
a first-trained-model storage section in which a first trained model is stored, the first trained model being constructed by machine learning in which first reference waveform data forming a first reference waveform having the first parameter on the horizontal axis and the second parameter on the vertical axis is used as teaching data, the first reference waveform having a peak portion including a known combination of a value of the first parameter and a value of the second parameter, and the first trained model being configured so that when a first window is applied on the horizontal axis for extracting a predetermined range of data from the first reference waveform data, and an input of first partial data corresponding to the first window is received, the first trained model outputs a first index in response to the input, the first index representing a peak portion or a non-peak portion for each of a plurality of first-partial-data elements constituting the first partial data;
a second-trained-model storage section in which a second trained model is stored, the second trained model being constructed by machine learning in which second reference waveform data forming a second reference waveform having the first parameter on the horizontal axis and the second parameter on the vertical axis is used as teaching data, the second reference waveform having a peak portion including a known combination of a value of the first parameter and a value of the second parameter, and the second trained model being configured so that when a second window is applied on the horizontal axis for extracting a predetermined range of data from the second reference waveform data in, the second window having a different width from the first window, and an input of second partial data corresponding to the second window is received, the second trained model outputs a second index in response to the input, the second index representing a peak portion or a non-peak portion for each of a plurality of second-partial-data elements constituting the second partial data;
a first-index output processor configured to extract first analysis-target partial data corresponding to the first window from the analysis-target data, and to input the first analysis-target partial data into the first trained model to obtain an output of the first index for each of a plurality of first analysis-target-data elements constituting the first analysis-target partial data;
a second-index output processor configured to extract second analysis-target partial data corresponding to the second window from the analysis-target data, and to input the second analysis-target partial data into the second trained model to obtain an output of the second index for each of a plurality of second analysis-target-data elements constituting the second analysis-target partial data; and
a peak portion estimator configured to estimate a peak portion from the analysis-target data, based on the first index obtained as the output from the first-index output processor and the second index obtained as the output from the second-index output processor.

3. The waveform-analyzing device according to claim 2, wherein:
information of a sampling rate in a measurement by which the analysis-target data was acquired is related to the same analysis-target data; and
the width of the first window is determined based on the sampling rate.

4. The waveform-analyzing device according to claim 2, wherein:
information of a type of detector used in a measurement by which the analysis-target data was acquired is related to the same analysis-target data; and
the width of the second window is determined beforehand based on the type of detector.

5. The waveform-analyzing device according to claim 2, wherein the second window is configured to extract the entirety of the analysis-target data.

6. The waveform-analyzing device according to claim 2, wherein the first trained model and the second trained model are constructed using different architectures.

7. The waveform-analyzing device according to claim 2, wherein the peak portion estimator is configured to give priority to an index representing a peak portion in estimating a peak portion from the analysis-target data if an index outputted for one measurement data element by the first-index output processor is different from an index outputted for the same measurement data element by the second-index output processor.
